(19) United States
(12) Patent Application Publication
(10) Pub. No.: US 2015/0060015 A1
(43) Pub. Date: Mar. 5, 2015

(54) AIR DUCT

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: ZI-XUAN ZHANG, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/014,425

(22) Filed: Aug. 30, 2013

(51) Int. Cl. H05K 7/20

(52) U.S. Cl. CPC H05K 7/20145
USPC 165/96

(57) ABSTRACT

An air duct includes two opposite sidewalls, a top wall connected between top sides of the sidewalls, and a blocking member detachably mounted to an outer surface of one of the sidewalls.

### BACKGROUND

1. Technical Field

The present disclosure relates to an air duct.

2. Description of Related Art

Air flowing toward central processing units (CPUs) is often partially blown toward memory slots positioned adjacent to the CPUs, which will lower the heat dissipation efficiency for the CPUs.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an embodiment of an air duct, together with a motherboard.

FIG. 2 is an exploded, isometric view of the air duct of FIG. 1.

FIGS. 3 and 4 are assembled, isometric view of the air duct of FIG. 1, but showing different using states.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

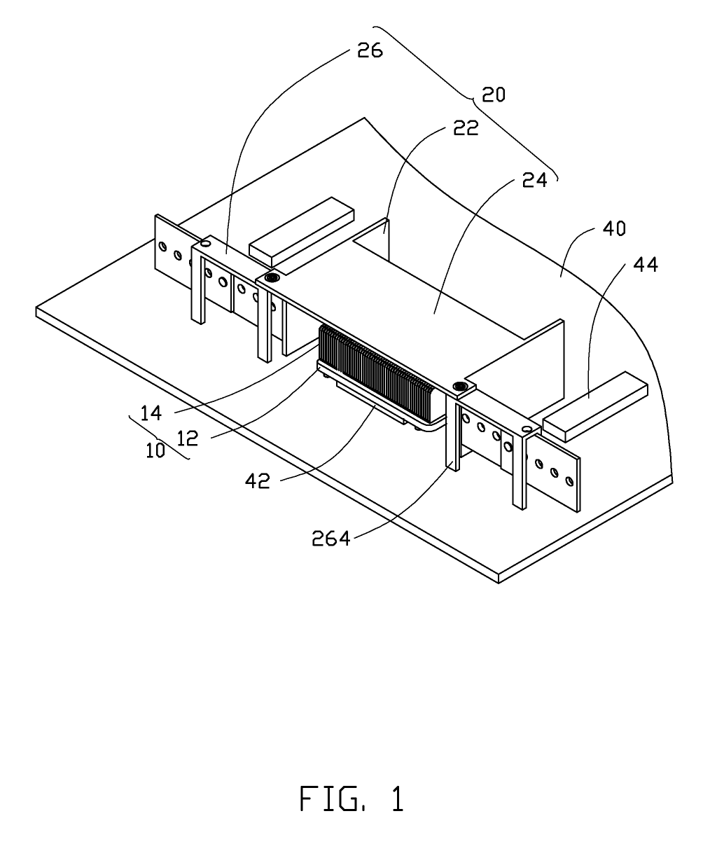

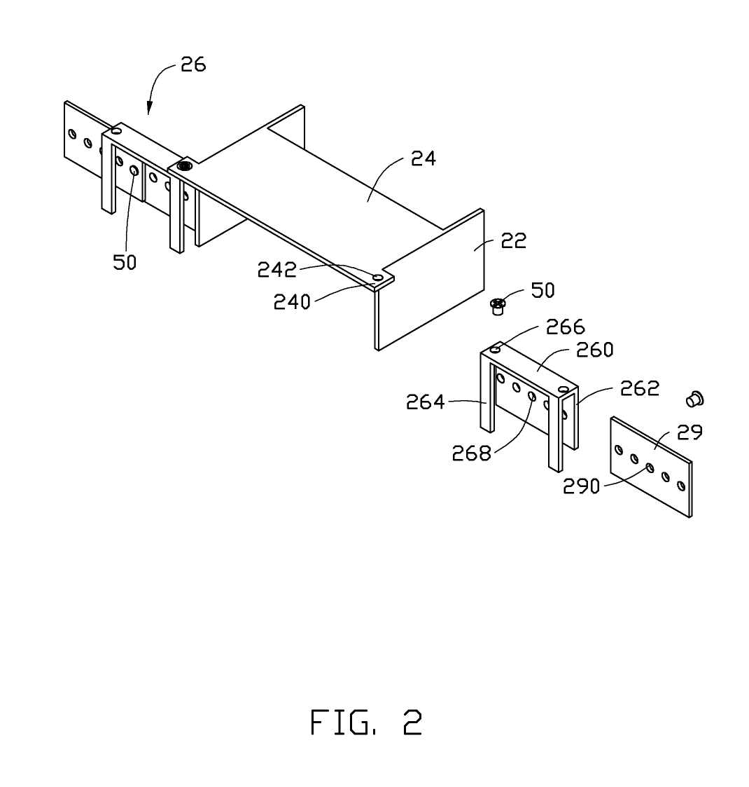

FIGS. 1 and 2 show an embodiment of an air duct 20 mounted on a motherboard 40.

A central processing unit (CPU) 42 and two memory slot groups 44 positioned at opposite sides of the CPU 42 are mounted on the motherboard 40. A heat sink 10 is placed on the CPU 42.

The heat sink 10 includes a board 12 and a plurality of fins 14 extending up from a top of the board 12 in a substantially perpendicular manner.

The air duct 20 includes two opposite sidewalls 22, a top wall 24 connected between top sides of the sidewalls 22, and two blocking members 26.

Two tabs 240 extend out from opposite ends of a front side of the top wall 24. Each tab 240 defines a through hole 242.

Each blocking member 26 includes a connecting piece 260, a blocking piece 262 perpendicularly extending down from a rear side of the connecting piece 260, two supporting pieces 264 perpendicularly extending down from a front side of the connecting piece 260, and two blocking plates 29. The connecting piece 260 defines a fixing hole 266 in an end. The blocking piece 262 longitudinally defines a plurality of fixing holes 268. Each blocking plate 29 longitudinally defines a plurality of fixing holes 290. Two fasteners 50 respectively extend through two of the fixing holes 290 of the blocking plates 29 and then are respectively fixed in two of the fixing holes 268 of the blocking pieces 262, to fix the blocking members 29 to the blocking pieces 262, to lengthen the blocking members 26. Because the blocking members 29 each define a plurality of fixing holes 290, and the blocking pieces 262 each define a plurality of fixing holes 268, the length of the blocking members 26 are adjustable.

Another two fasteners 50 extend through the through holes 242, and then are engaged in the fixing holes 266, to perpendicularly fix the blocking members 26 to outer surfaces of the sidewalls 22.

In use, the air duct 20 accommodates the heat sink 10, with the sidewalls 22 substantially parallel to the fins 14 and respectively contacting the outmost two fins 14. The supporting pieces 264 and the sidewalls 22 are supported on the motherboard 40. The blocking members 26 are located in front of and block the memory slot groups 44.

The blocking members 26 block the memory slot groups 44, to prevent airflow from flowing toward the memory slot groups 44, and guide the airflow toward the heat sink 10 to dissipate heat generated by the CPU 42.

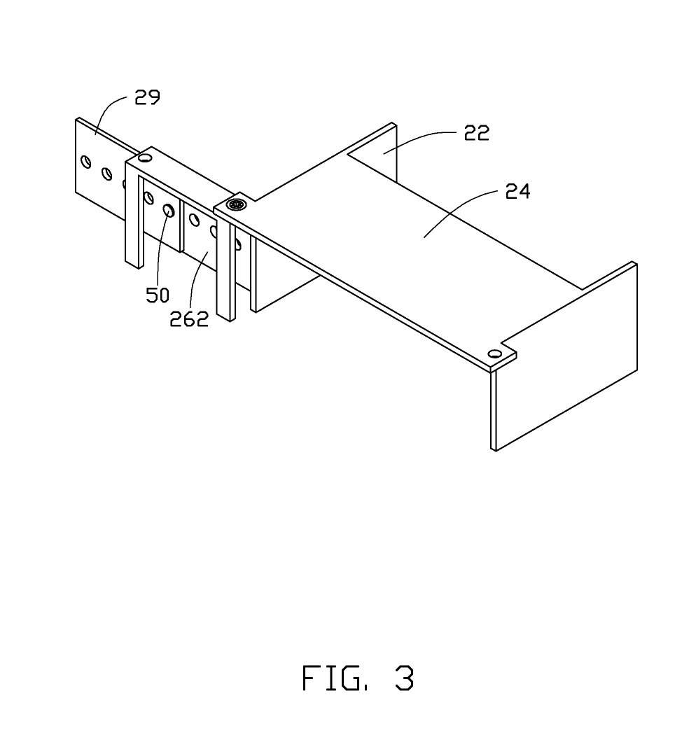

Referring to FIG. 3, in another embodiment, one of the blocking members 26 can be omitted.

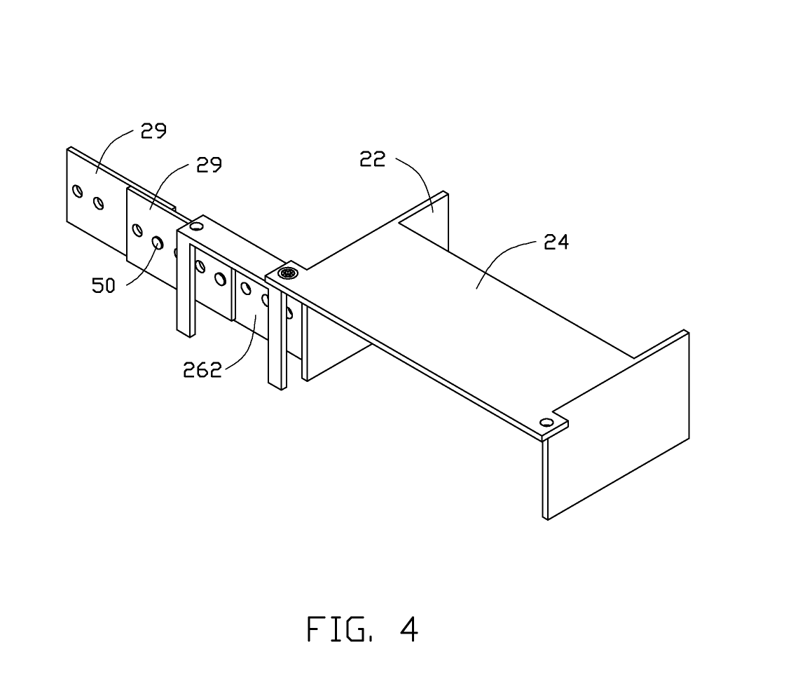

Referring to FIG. 4, in another embodiment, another blocking plate 29 can be mounted to the blocking plate 29, to further lengthen the corresponding blocking member 26.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. An air duct, comprising two opposite sidewalls, a top wall connected between top sides of the sidewalls, and a blocking member detachably mounted to an outer surface of one of the sidewalls.

2. The air duct of claim 1, wherein the blocking member comprises a blocking piece and a blocking plate detachably mounted to the blocking piece, a position of the blocking plate is adjustable along a direction perpendicular to the sidewalls.

3. The air duct of claim 2, wherein the blocking piece defines a plurality of first fixing holes along the direction perpendicular to the sidewalls, the blocking plate defines a plurality of second fixing holes along the direction perpendicular to the sidewalls, a fastener selectively extends through one of the second fixing holes and then is engaged in one of the first fixing holes.

4. The air duct of claim 2, wherein two tabs extend out from opposite ends of the top wall, a connecting piece is connected to a top side of the blocking piece, a fastener extends through the tab and then is engaged in the connecting piece.

5. The air duct of claim 4, wherein a supporting piece extends down from the connecting piece.
